(19) United States
(12) Patent Application Publication
(10) Pub. No.: US 2020/0027813 A1
(43) Pub. Date: Jan. 23, 2020

(54) MICROELECTRONICS PACKAGE WITH A COMBINATION HEAT SPREADER/RADIO FREQUENCY SHIELD

(71) Applicant: Intel Corporation, Santa Clara, CA (US)

(72) Inventors: Bok Eng Cheah, Bukit Gambir (MY); Jackson Chung Peng Kong, Tanjung Tokong (MY); Kooi Chi Ooi, Glugor (MY); Ping Ping Ooi, Betterworth (MY)

(21) Appl. No.: 16/453,605

(22) Filed: Jun. 26, 2019

(30) Foreign Application Priority Data
Jul. 23, 2018 (MY) PI 2018702562

(51) Int. Cl. H01L 23/367; H01L 23/373; H01L 23/552

(52) U.S. Cl. CPC H01L 23/367; H01L 23/552; H01L 23/3736

(57) ABSTRACT

Described herein are microelectronics packages and methods for manufacturing the same. The microelectronics package may include a base package, an ancillary package, and an electrically isolated metal layer. The base package may include a base die. The ancillary package may include an ancillary component. The ancillary package may be located on top of the base package. The electrically isolated metal layer may be located at least partially within a layer of the base package such that a portion of the electrically isolated metal layer contacts at least one surface of the base die and is located in between the base die and the ancillary component.

### PRIORITY APPLICATION

This application claims the benefit of priority to Malaysian Application Serial Number PI 2018702562, filed Jul. 23, 2018, which is incorporated herein by reference in its entirety.

### TECHNICAL FIELD

Embodiments described generally herein relate to microelectronic packages and microelectronic packages manufacturing. Some embodiments relate to using an electrically isolated metal layer to control heat transfer and RF interference within a stacked package.

### BACKGROUND

A microelectronics package may include a plurality of die. During operations, the plurality of die may generate heat and RF interference. The heat generated needs to be removed to prevent the plurality of die from overheating and the RF interference needs to be mitigated to preserve electrical integrity.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIGS. 1A, 1B, and 1C illustrate a side sectional view, a top view, and a top sectional view, respectively, of a microelectronics package in accordance with embodiments disclosed herein.

FIGS. 2A and 2B illustrate a side sectional view and a top sectional view, respectively, of a microelectronics package in accordance with embodiments disclosed herein.

FIGS. 3A-3H illustrate an example method for manufacturing a microelectronics package in accordance with embodiments disclosed herein.

FIG. 4 illustrates an example schematic of a computing device in accordance with embodiments disclosed herein.

### DETAILED DESCRIPTION

As disclosed herein, platform miniaturization, such as die stacking, may lead to problems with electromagnetic interference between components as well as thermal management issues. For example, components in close proximity to one another may generate electromagnetic interference, sometimes referred to as crosstalk. In addition, the various components may generate heat that may be dissipated to adjacent components and cause warping, cracking, and delamination within a stacked die package.

As disclosed herein, a 3D stacked package, such as a package-on-package (POP), may include a radio frequency (RF) shield and a thermal heat spreader as a single component of the package. For example, the package may include an ancillary package, sometimes referred to as a top package, and a base package, sometimes referred to as a bottom package. Examples of the ancillary package include, but are not limited to, a radio frequency transceiver integrated circuit (RFIC) and one or more memory dies. An example of the base package includes, but is not limited to, a central processing unit (CPU) with a platform controller hub (PCH).

As disclosed herein, the ancillary package may be stacked on top of the base package and an electrically isolated metal layer, also referred to as a combination heat spreader/RF shield, may be located in between the base package and the ancillary package. The combination heat spreader/RF shield may be a layer within the package. For example, the combination heat spreader/RF shield may be a metal layer that is deposited on at least one surface and/or sidewall of a die within the base package or the ancillary package. The combination heat spreader/RF shield may extend across the footprint of the base package. In addition, the combination heat spreader/RF shield may associate to a reference voltage through at least one through mold interconnect. The combination heat spreader/RF shield may electrically isolate the dies of the ancillary package from the dies of the base package and provide a thermal dissipation path for heat to be removed from the dies.

Non-limiting and non-exhaustive advantages of the invention include improved device and interconnect electrical (e.g., signal integrity) performance through enhanced electromagnetic interference (EMI) and/or RF shielding, thus allowing device performance scaling and/or integration. In addition, platform miniaturizations may be achieved through device integration such as RFIC or memory die stacking on logic or application processors. Furthermore, improved device heat flow and/or thermal dissipation through high thermal conductivity path (e.g. metal pathways) between silicon dies and package peripheral sidewalls may be achieved.

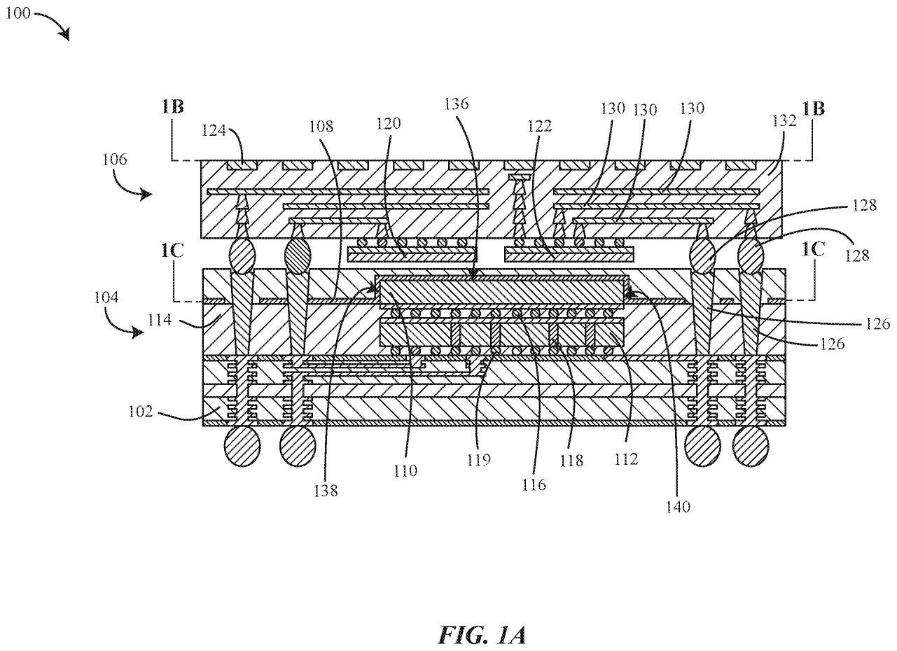

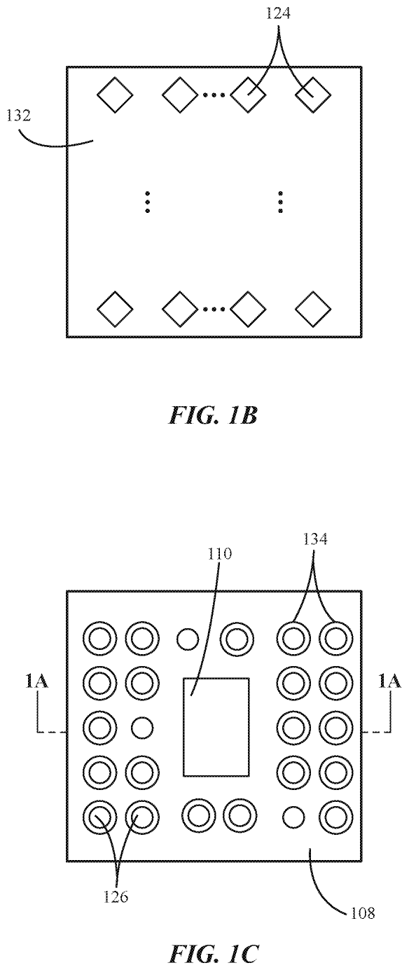

Turning now to the figures, FIGS. 1A, 1B, and 1C illustrate a side sectional view, a top view, and a top sectional view, respectively, of a microelectronics package 100 in accordance with embodiments disclosed herein. The microelectronics package 100 may include, a base package 104, an ancillary package 106, and a combination heat spreader/RF shield 108. Base package 104 may include a substrate 102, a first die 110, a second die 112, and a mold layer 114. First die 110 may be electrically couple to second die 112 via one or more solder bumps 116. First die 110 and second die 112 may be electrically couple to substrate 102 through one or more through silicon via 118 and package bump 119.

Ancillary package 106 may include a first RFIC 120, a second RFIC 122, and a patch antenna array 124. One or more through mold interconnects 126 and package solder interconnects 128 may connect the ancillary package 106 to substrate 102. In addition, one or more traces 130 may be used to connect first RFIC 120 and second RFIC 122 to package solder interconnects 128. Traces 130 as well as patch antenna array 124 may be embedded within a dielectric material 132.

As shown in FIGS. 1A and 1C, combination heat spreader/RF shield 108 may span a footprint of base package 104. For example, combination heat spreader/RF shield 108 may cover a top surface of base package 104. Having combination heat spreader/RF shield 108 span the footprint of base package 104 may allow combination heat spreader/RF shield 108 to act as a shield and hinder or attenuate the transfer of electromagnetic radiation between base package 104 and ancillary package 106. Stated another way, by having combination heat spreader/RF shield 108 span the footprint of base package 104 crosstalk between the base package 104 and the ancillary package 106 may be reduced or eliminated.

To allow ancillary package 106 to be in electrical communication with the motherboard (not shown), substrate 102, or base package 104, one or more holes 134 may allow through mold interconnects 126 to pass through combination heat spreader/RF shield 108. One or more of holes 134 may have a diameter that is greater than the diameter of a corresponding through mold interconnect 126 without electrically coupling the through mold interconnect 126 with the combination heat spreader/RF shield 108. In an embodiment, holes 134 may be filled with a dielectric layer, such as a mold layer, to electrically isolate through mold interconnects 126 from combination heat spreader/RF shield 108. In addition, a diameter of one or more of holes 134 may be the same as or smaller than the diameter of a corresponding through mold interconnect 126 such that the corresponding through mold interconnect 126 is electrically coupled to combination heat spreader/RF shield 108 (e.g., the corresponding through mold interconnects 126 may be in direct contact with the combination heat spreader/RF shield 108 without the dielectric or mold layer in between the structures). Having combination heat spreader/RF shield 108 contact through mold interconnect 126 may allow combination heat spreader/RF shield 108 to be coupled to a reference voltage such as a ground (Vss) reference voltage. Thus, any electrical current generated within combination heat spreader/RF shield 108 due to electromagnetic radiation may be dissipated to ground.

Combination heat spreader/RF shield 108 may contact first die 110. For example, combination heat spreader/RF shield 108 may rest against a top surface 136 as well as side surfaces 138 and 140. Contact with first die 110 on one or more sides may allow for greater heat transfer from first and second dies 110 and 112 as well as base package 104 to combination heat spreader/RF shield 108 by increased contact surface area. Thermal interface materials, such as thermal greases or other compounds, may be used to dissipate heat away from base package 104 and ancillary package 106.

Combination heat spreader/RF shield 108 may be formed from any material that facilitates conduction of heat as well as provides electromagnetic shielding between base package 104 and ancillary package 106. For example, combination heat spreader/RF shield 108 may be formed from silver, copper, nickel, etc. Combination heat spreader/RF shield 108 may be applied to base package 104 via a variety of techniques including, but not limited to, vapor deposition, sputtering, electroplating, etc. The thickness of combination heat spreader/RF shield 108 may range from about 5 microns to about 80 microns depending on an anticipate heat load and/or electromagnetic interference that may be expected.

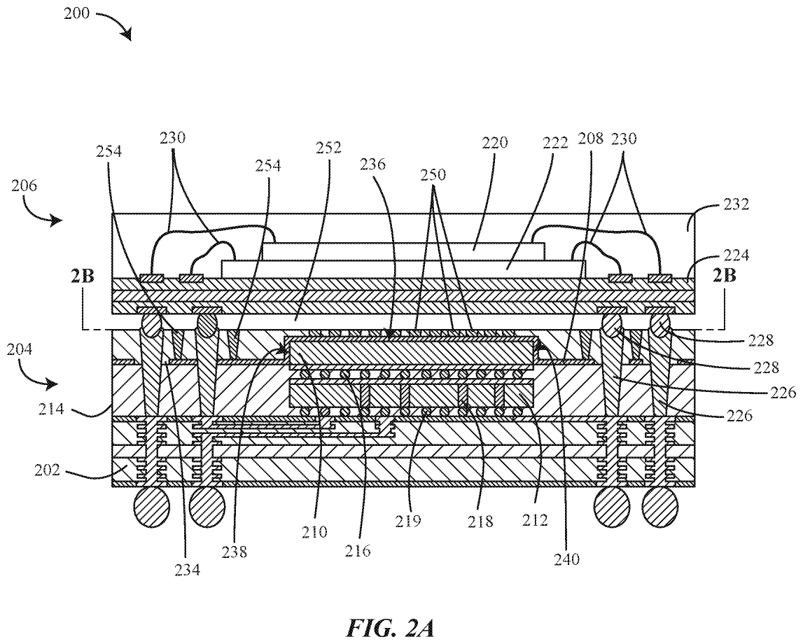

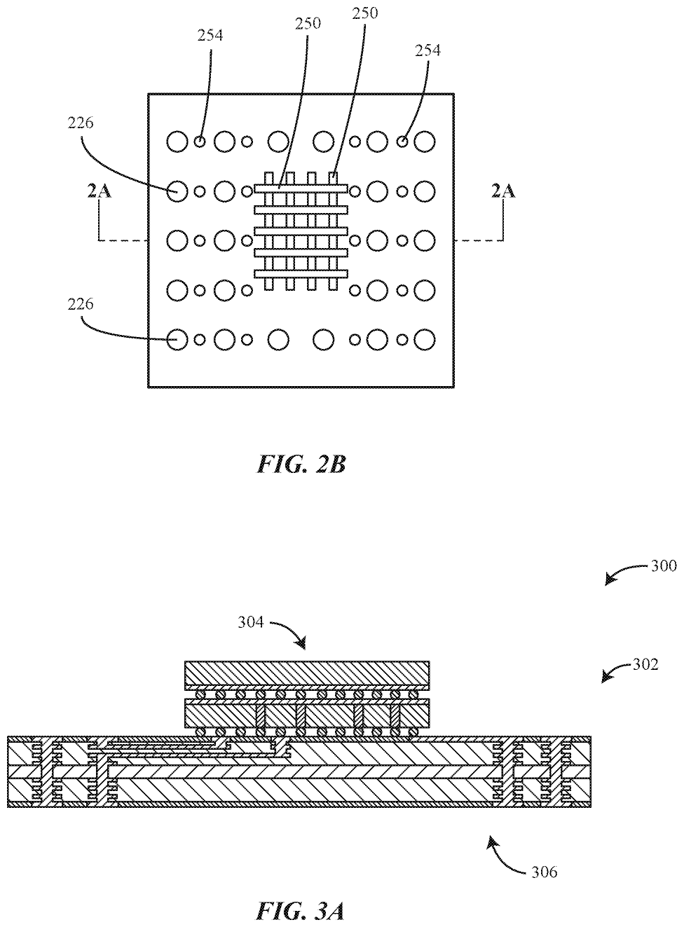

Turning now to FIGS. 2A and 2B, FIGS. 2A and 2B illustrate a side sectional view and a sectional top view, respectively, of a microelectronics package 200 in accordance with embodiments disclosed herein.

The microelectronics package 200 may include a base package 204, an ancillary package 206, and a combination heat spreader/RF shield 208. Base package 204 may include a substrate 202, a first die 210, a second die 212, and a mold layer 214. First die 210 may be electrically couple to second die 212 via one or more solder bumps 216. First die 210 and second die 212 may also be electrically couple to substrate 202 through one or more through silicon via 218 and package bump 219.

Ancillary package 206 may include a third die 220 and a fourth die 222 attached to a substrate 224. One or more through mold interconnects 226 and package solder interconnects 228 may connect the ancillary package 206 to substrate 202. In addition, one or more wire bonds 230 may be used to connect third die 220 and fourth die 222 to package solder interconnects 228. Wire bonds 230 as well as other traces may be embedded within a dielectric material 232.

As shown in FIGS. 2A and 2B, combination heat spreader/RF shield 208 may span a footprint of base package 204. For example, combination heat spreader/RF shield 208 may cover a top surface of base package 204. Having combination heat spreader/RF shield 208 span the footprint of base package 204 may allow combination heat spreader/RF shield 208 to act as a shield and hinder or attenuate the transfer of electromagnetic radiation between base package 204 and ancillary package 206. Stated another way, by having combination heat spreader/RF shield 208 span the footprint of base package 204 crosstalk between the base package 204 and the ancillary package 206 may be reduced or eliminated.

In addition, combination heat spreader/RF shield 208 may include one or more extended surfaces 250. Extended surfaces 250 may form a mesh as shown in FIG. 2B. The mesh may act as a Faraday cage that partially surround or cover one or more surfaces of first die 210. Extended surfaces 250 also may provide additional surface area for the dissipation of heat from base package 204 into a space 252 formed between base package 204 and ancillary package 206. In addition to forming a mesh, peripheral vertical thermal spreaders 254 may extend from combination heat spreader/RF shield 208. Just as with extended surfaces 250, peripheral vertical thermal spreaders 254 may extend from combination heat spreader/RF shield 208 to space 252 to allow heat to flow from peripheral regions of combination heat spreader/RF shield 208 into space 252.

To allow ancillary package 206 to be in electrical communication with the motherboard (not shown), substrate 202, or base package 204, one or more holes 234 may allow through mold interconnects 226 to pass through combination heat spreader/RF shield 208. One or more of holes 234 may have a diameter that is greater than the diameter of a corresponding through mold interconnect 226 without electrically coupling the through mold interconnect 226 with the combination heat spreader/RF shield 208. In an embodiment, holes 234 may be filled with a dielectric layer, such as a mold layer, to electrically isolate through mold interconnects 226 from combination heat spreader/RF shield 208. In addition, a diameter of one or more of holes 234 may be the same as or smaller than the diameter of a corresponding through mold interconnect 226 such that the corresponding through mold interconnect 226 is electrically coupled to combination heat spreader/RF shield 208 (e.g., the corresponding through mold interconnects 226 may be in direct contact with combination heat spreader/RF shield 208 without the dielectric or mold layer in between structures). Having combination heat spreader/RF shield 208 contact through mold interconnect 226 may allow combination heat spreader/RF shield 208 to be coupled to a reference voltage such as a ground (Vss) reference voltage. Thus, any electrical current generated within combination heat spreader/RF shield 208 due to electromagnetic radiation may be dissipated to ground. In an embodiment, extended surfaces 250 and peripheral vertical thermal spreaders 254 may also be coupled to a reference voltage (e.g., a ground (Vss) reference voltage).

Combination heat spreader/RF shield 208 may contact first die 210. For example, combination heat spreader/RF shield 208 may rest against a top surface 236 as well as side surfaces 238 and 240. Contact with first die 210 on one or more sides may allow for greater heat transfer from first and second dies 210 and 212 as well as base package 204 to combination heat spreader/RF shield 208 by increased contact surface area. Thermal interface materials, such as thermal greases or other compounds, may be disposed within space 252 to dissipate heat away from base package 204 and ancillary package 206.

Combination heat spreader/RF shield 208, extended surfaces 250, and peripheral vertical thermal spreaders 254 may be formed from any material that facilitates conduction of heat as well as provides electromagnetic shielding between base package 204 and ancillary package 206. For example, combination heat spreader/RF shield 208 may be formed from silver, copper, nickel, etc. Combination heat spreader/RF shield 208 may be applied to base package 204 via a variety of techniques including, but not limited to, vapor deposition, sputtering, electroplating, etc. The thickness of combination heat spreader/RF shield 208 may range from about 5 microns to about 80 microns depending on an anticipate heat load and/or electromagnetic interference that may be expected.

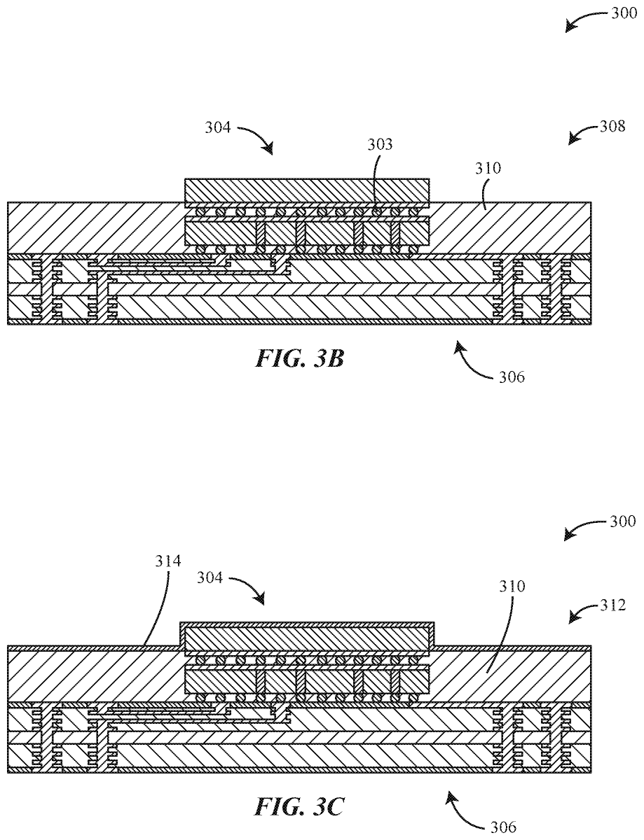

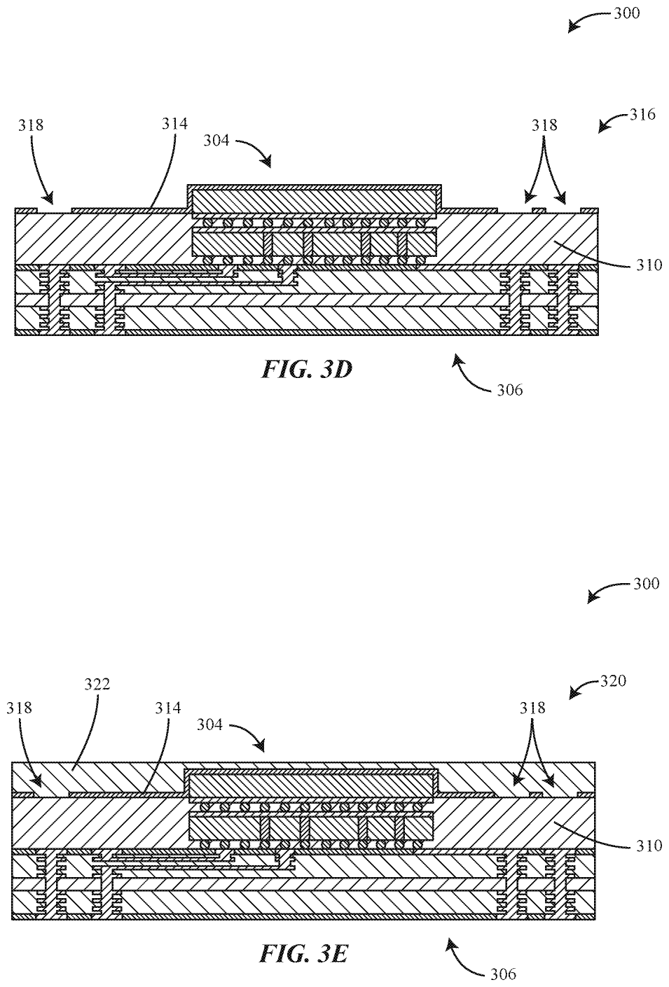

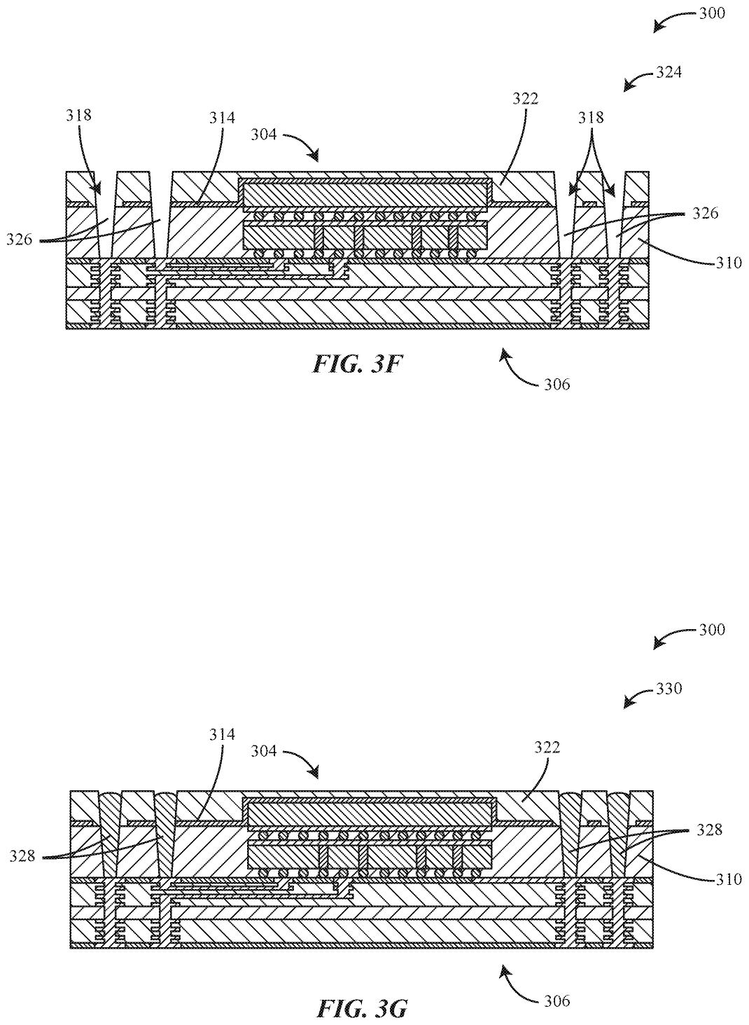

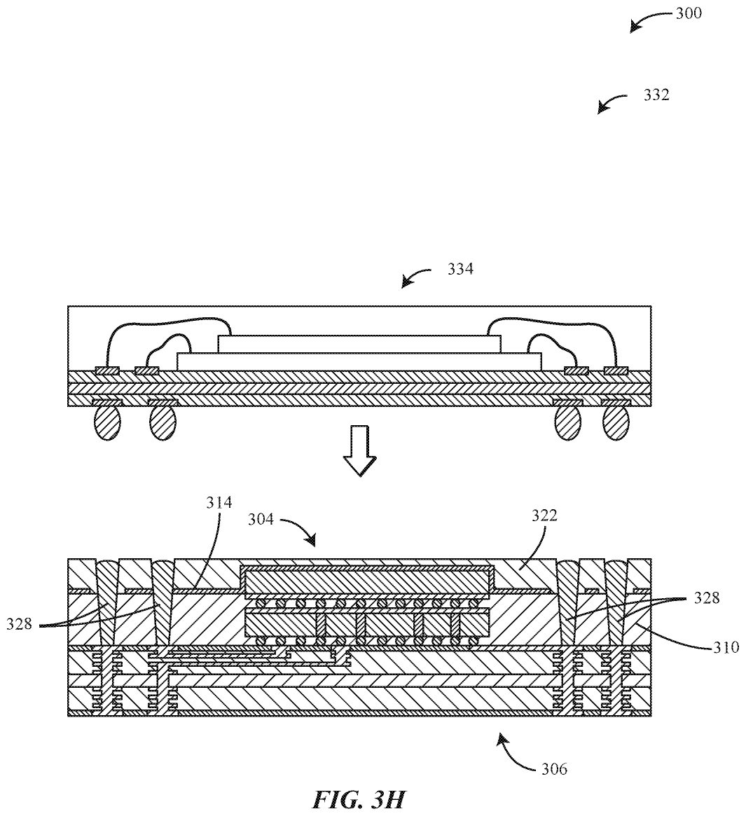

FIGS. 3A-3H illustrate the method stages for a method 300 for manufacturing a microelectronics package, such as package 100 or package 200, in accordance with embodiments disclosed herein. Method 300 may begin at stage 302 where stacked dice 304 may be attached to a substrate 306. From stage 302, method 300 may proceed to stage 308 where a mold layer 310 may be formed to partially encapsulation stacked dice 304. In an embodiment, mold layer 310 disposed on substrate 306 to partially encapsulate stacked dice 304 may have a thickness about 10 microns to 50 microns higher and away from a silicon metallization layer of first die 303 to avoid electrical short or leakage with the combination heat spreader/RF shield 314 (see FIG. 3C).

From stage 308 method 300 may proceed to stage 312 where a combination heat spreader/RF shield 314 may be formed. Combination heat spreader/RF shield 314 may be formed, for example, by a deposition, an electroplating or metal sputtering process. As disclosed herein, combination heat spreader/RF shield 314 may be formed to span the footprint of substrate 306 and/or mold layer 310. In addition, combination heat spreader/RF shield 314 may be formed so as to contact one or more surfaces of the dice that make up stacked dice 304 as disclosed herein.

From stage 312 method 300 may proceed to stage 316 where holes 318 may be formed in combination heat spreader/RF shield 314. As disclosed herein, holes 318 may allow combination heat spreader/RF shield 314 to be electrically isolated from interconnects that may be formed in mold layer 310. From stage 316 method 300 may proceed to stage 320 where a mold layer 322 may be formed. Mold layer 322 may fully or partially cover combination heat spreader/RF shield 314.

From stage 320 method 300 may proceed to stage 324 where through mold trenches 326 may be formed. As shown in FIGS. 3E and 3F, when forming one of the through mold trenches, it may pass through combination heat spreader/RF shield 314 where holes 318 where not formed. As a result, when through mold interconnects 328 are formed in stage 330, the corresponding through mold interconnect 328 may contact combination heat spreader/RF shield 314 so as to electrically couple through mold interconnect 328 with combination heat spreader/RF shield 314. For example, one of through mold interconnects 328 that associates to a reference voltage source (e.g., Vss reference source) through example a circuitry in substrate 306, may be electrically coupled to combination heat spreader/RF shield 314 so as to associate the combination heat spreader/RF shield 314 or other connect it to a reference voltage.

In an embodiment, though mold interconnects 328 that carries input/output (I/O) signal and/or power may pass through holes 318 and electrically isolated from combination heat spreader/RF shield 314.

From stage 330 where through mold interconnects 328 are formed, method 300 may proceed to stage 332 where an ancillary package 334, such as ancillary package 106 or ancillary package 206, may be attached to the base package formed in stages 302, 308, 312, 316, 320, 324, and 330 through example a solder reflow or surface mounting process.

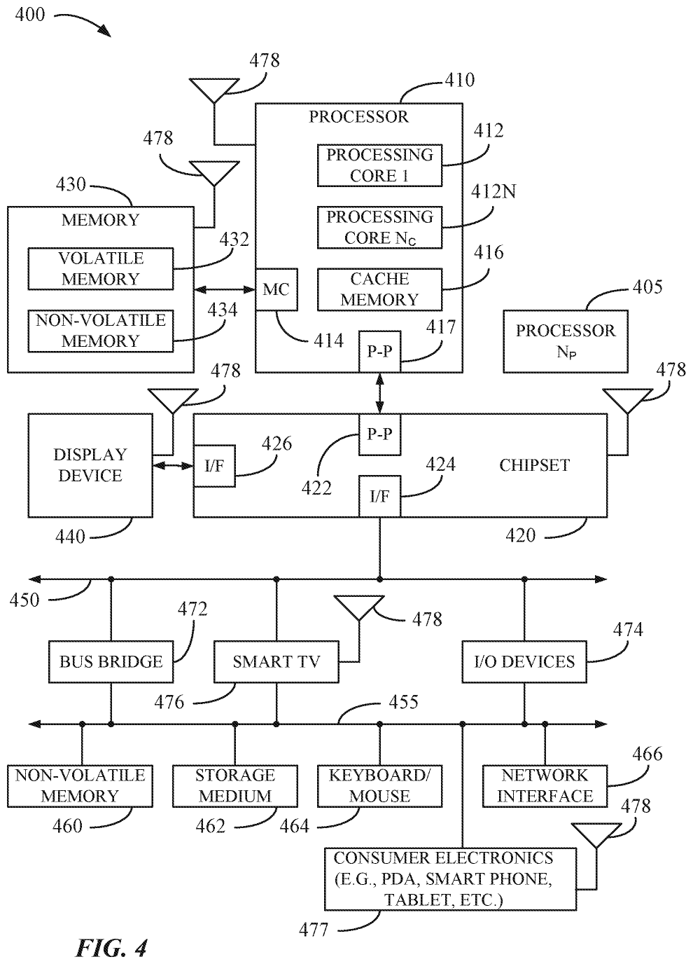

FIG. 4 illustrates a system level diagram, according to one embodiment of the invention. For instance, FIG. 4 depicts an example of an electronic device (e.g., system) including microelectronics package 100 or microelectronics package 200. FIG. 4 is included to show an example of a higher level device application for the present invention. In one embodiment, system 400 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 400 is a system on a chip (SOC) system.

In one embodiment, processor 410 has one or more processing cores 412 and 412N, where 412N represents the Nth processor core inside processor 410 where N is a positive integer. In one embodiment, system 400 includes multiple processors including 410 and 405, where processor 405 has logic similar or identical to the logic of processor 410. In some embodiments, processing core 412 includes, but is not limited to, pre-fetch logic to fetch instructions, decode logic to decode the instructions, execution logic to execute instructions and the like. In some embodiments, processor 410 has a cache memory 416 to cache instructions and/or data for system 400. Cache memory 416 may be organized into a hierarchal structure including one or more levels of cache memory.

In some embodiments, processor 410 includes a memory controller 414, which is operable to perform functions that enable the processor 410 to access and communicate with memory 430 that includes a volatile memory 432 and/or a non-volatile memory 434. In some embodiments, processor 410 is coupled with memory 430 and chipset 420. Processor 410 may also be coupled to a wireless antenna 478 to communicate with any device configured to transmit and/or receive wireless signals. In one embodiment, the wireless antenna interface 478 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 432 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 434 includes, but is not limited to, flash memory, phase change memory (PCM), read-only memory (ROM), electrically erasable programmable read-only memory (EEPROM), or any other type of non-volatile memory device.

Memory 430 stores information and instructions to be executed by processor 410. In one embodiment, memory 430 may also store temporary variables or other intermediate information while processor 410 is executing instructions. In the illustrated embodiment, chipset 420 connects with processor 410 via Point-to-Point (PtP or P-P) interfaces 417 and 422. Chipset 420 enables processor 410 to connect to other elements in system 400. In some embodiments of the invention, interfaces 417 and 422 operate in accordance with a PtP communication protocol such as the Intel® QuickPath Interconnect (QPI) or the like. In other embodiments, a different interconnect may be used.

In some embodiments, chipset 420 is operable to communicate with processor 410, 405N, display device 440, and other devices 472, 476, 474, 460, 462, 464, 466, 477, etc. Chipset 420 may also be coupled to a wireless antenna 478 to communicate with any device configured to transmit and/or receive wireless signals.

Chipset 420 connects to display device 440 via interface 426. Display 440 may be, for example, a liquid crystal display (LCD), a plasma display, cathode ray tube (CRT) display, or any other form of visual display device. In some embodiments of the invention, processor 410 and chipset 420 are merged into a single SOC. In addition, chipset 420 connects to one or more buses 450 and 455 that interconnect various elements 474, 460, 462, 464, and 466. Buses 450 and 455 may be interconnected together via a bus bridge 472. In one embodiment, chipset 420, via interface 424, couples with a non-volatile memory 460, a mass storage device(s) 462, a keyboard/mouse 464, a network interface 466, smart TV 476, and consumer electronics 477, etc.

In one embodiment, mass storage device 462 includes, but is not limited to, a solid state drive, a hard disk drive, a universal serial bus flash memory drive, or any other form of computer data storage medium. In one embodiment, network interface 466 is implemented by any type of well known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 4 are depicted as separate blocks within the system 400, the functions performed by some of these blocks may be integrated within a single semiconductor circuit or may be implemented using two or more separate integrated circuits. For example, although cache memory 416 is depicted as a separate block within processor 410, cache memory 416 (or selected aspects of 416) can be incorporated into processor core 412.

### ADDITIONAL NOTES & EXAMPLES

Example 1 is a microelectronics package comprising: a base package including a base die; an ancillary package including an ancillary component, the ancillary package located on top of the base package; and an electrically isolated metal layer located at least partially within a layer of the base package such that a portion of the electrically isolated metal layer contacts at least one surface of the base die and is located in between the base die and the ancillary component.

In Example 2, the subject matter of Example 1 optionally includes wherein the ancillary component includes a memory die.

In Example 3, the subject matter of any one or more of Examples 1-2 optionally include wherein the ancillary component includes a transceiver integrated circuit.

In Example 4, the subject matter of any one or more of Examples 1-3 optionally include wherein the base die includes a central processing unit (CPU) with a platform controller hub (PCH).

In Example 5, the subject matter of any one or more of Examples 1-4 optionally include wherein the layer of the base package is a mold layer.

In Example 6, the subject matter of any one or more of Examples 1-5 optionally include wherein the electrically isolated metal layer extends across a footprint of the base package.

In Example 7, the subject matter of any one or more of Examples 1-6 optionally include wherein the electrically isolated metal layer contacts a top surface and at least one side surface of the base die.

In Example 8, the subject matter of any one or more of Examples 1-7 optionally include wherein the electrically isolated metal layer contacts all but one surface of the base die.

In Example 9, the subject matter of any one or more of Examples 1-8 optionally include wherein the electrically isolated metal layer is composed of copper or silver.

In Example 10, the subject matter of any one or more of Examples 1-9 optionally include wherein a thickness of the electrically isolated metal layer is about 5 microns to about 80 microns.

In Example 11, the subject matter of any one or more of Examples 1-10 optionally include wherein the electrically isolated metal layer is electrically coupled to a ground (Vss) reference voltage.

In Example 12, the subject matter of any one or more of Examples 1-11 optionally include a through mold interconnect passing through the layer of the base package and electrically coupling the ancillary package to the electrically isolated metal layer and a trace of the base package.

In Example 13, the subject matter of any one or more of Examples 1-12 optionally include a through mold interconnect passing through the layer of the base package and electrically coupling the ancillary package to a trace of the base package but not the electrically isolated metal layer.

In Example 14, the subject matter of any one or more of Examples 1-13 optionally include a plurality of extended surfaces extending from the electrically isolated metal layer.

In Example 15, the subject matter of Example 14 optionally includes wherein the extended surfaces form a mesh pattern proximate the base die.

In Example 16, the subject matter of any one or more of Examples 14-15 optionally include wherein the extended surfaces form a Faraday cage proximate the base die.

Example 17 is a microelectronics package comprising: a base package including a central processing unit (CPU); an ancillary package including a memory die, the ancillary package located on top of the base package; and an electrically isolated metal layer located at least partially within a layer of the base package such that a portion of the electrically isolated metal layer contacts at least one surface of the CPU and is located in between the CPU and the memory die.

In Example 18, the subject matter of Example 17 optionally includes wherein the layer of the base package is a mold layer.

In Example 19, the subject matter of any one or more of Examples 17-18 optionally include wherein the electrically isolated metal layer extends across a footprint of the base package.

In Example 20, the subject matter of any one or more of Examples 17-19 optionally include wherein the electrically isolated metal layer contacts a top surface and at least one side surface of the CPU.

In Example 21, the subject matter of any one or more of Examples 17-20 optionally include wherein the electrically isolated metal layer contacts all but one surface of the CPU.

In Example 22, the subject matter of any one or more of Examples 17-21 optionally include wherein the electrically isolated metal layer is composed of copper or silver.

In Example 23, the subject matter of any one or more of Examples 17-22 optionally include microns.

In Example 24, the subject matter of any one or more of Examples 17-23 optionally include wherein the electrically isolated metal layer is electrically coupled to a ground reference.

In Example 25, the subject matter of any one or more of Examples 17-24 optionally include a through mold interconnect passing through the layer of the base package and electrically coupling the memory die to the electrically isolated metal layer and a trace of the base package.

In Example 26, the subject matter of any one or more of Examples 17-25 optionally include a through mold interconnect passing through the layer of the base package and electrically coupling the memory die to a trace of the base package but not the electrically isolated metal layer.

In Example 27, the subject matter of any one or more of Examples 17-26 optionally include a plurality of extended surfaces extending from the electrically isolated metal layer.

In Example 28, the subject matter of Example 27 optionally includes wherein the extended surfaces form a mesh pattern proximate the base die.

In Example 29, the subject matter of any one or more of Examples 27-28 optionally include wherein the extended surfaces form a Faraday cage proximate the base die.

Example 30 is a microelectronics package comprising: a base package including a central processing unit (CPU); an ancillary package including a transceiver integrated circuit, the ancillary package located on top of the base package; and an electrically isolated metal layer located at least partially within a layer of the base package such that a portion of the electrically isolated metal layer contacts at least one surface of the CPU and is located in between the CPU and the transceiver integrated circuit.

In Example 31, the subject matter of Example 30 optionally includes wherein the layer of the base package is a mold layer.

In Example 32, the subject matter of any one or more of Examples 30-31 optionally include wherein the electrically isolated metal layer extends across a footprint of the base package.

In Example 33, the subject matter of any one or more of Examples 30-32 optionally include wherein the electrically isolated metal layer contacts a top surface and at least one side surface of the CPU.

In Example 34, the subject matter of any one or more of Examples 30-33 optionally include wherein the electrically isolated metal layer contacts all but one surface of the CPU.

In Example 35, the subject matter of any one or more of Examples 30-34 optionally include wherein the electrically isolated metal layer is composed of copper or silver.

In Example 36, the subject matter of any one or more of Examples 30-35 optionally include wherein a thickness of the electrically isolated metal layer is about 5 microns to about 80 microns.

In Example 37, the subject matter of any one or more of Examples 30-36 optionally include wherein the electrically isolated metal layer is electrically coupled to a ground (Vss) reference voltage.

In Example 38, the subject matter of any one or more of Examples 30-37 optionally include a through mold interconnect passing through the layer of the base package and electrically coupling the transceiver integrated circuit to the electrically isolated metal layer and a trace of the base package.

In Example 39, the subject matter of any one or more of Examples 30-38 optionally include a through mold interconnect passing through the layer of the base package and electrically coupling the transceiver integrated circuit to a trace of the base package but not the electrically isolated metal layer.

In Example 40, the subject matter of any one or more of Examples 30-39 optionally include a plurality of extended surfaces extending from the electrically isolated metal layer.

In Example 41, the subject matter of Example 40 optionally includes wherein the extended surfaces form a mesh pattern proximate the base die.

In Example 42, the subject matter of any one or more of Examples 40-41 optionally include wherein the extended surfaces form a Faraday cage proximate the base die.

Example 43 is a method of manufacturing a stacked package, the method comprising: attaching a base die to a substrate to form a base package; attaching a combination heat spreader/radio frequency (RF) shield to the base die; and attaching an ancillary package to the base package such that the electrically isolated metal layer is located in between the base package and ancillary package, the ancillary package including an ancillary component.

In Example 44, the subject matter of Example 43 optionally includes wherein the ancillary component includes a memory die.

In Example 45, the subject matter of any one or more of Examples 43-44 optionally include wherein the ancillary component includes a transceiver integrated circuit.

In Example 46, the subject matter of any one or more of Examples 43-45 optionally include wherein the base die includes a central processing unit (CPU) with a platform controller hub (PCH).

In Example 47, the subject matter of any one or more of Examples 43-46 optionally include forming a mold layer on top of the electrically isolated metal layer such that the mold layer is located in between the ancillary package and the electrically isolated metal layer.

In Example 48, the subject matter of any one or more of Examples 43-47 optionally include wherein attaching the electrically isolated metal layer to the base die includes attaching the electrically isolated metal layer to a top surface and at least one side surface of the base die.

In Example 49, the subject matter of any one or more of Examples 43-48 optionally include wherein attaching the electrically isolated metal layer to the base die includes attaching the electrically isolated metal layer to all but one surface of the base die.

In Example 50, the subject matter of any one or more of Examples 43-49 optionally include electrically coupling the electrically isolated metal layer to a ground (Vss) reference voltage.

In Example 51, the subject matter of any one or more of Examples 43-50 optionally include forming a through mold interconnect passing through a layer of the base package; and electrically coupling the ancillary package to the electrically isolated metal layer and a trace of the base package.

In Example 52, the subject matter of any one or more of Examples 43-51 optionally include forming a through mold interconnect passing through a layer of the base package; and electrically coupling the ancillary package to a trace of the base package but not the electrically isolated metal layer.

In Example 53, the subject matter of any one or more of Examples 43-52 optionally include forming a plurality of extended surfaces extending from the electrically isolated metal layer.

In Example 54, the subject matter of Example 53 optionally includes wherein forming the extended surfaces includes forming the extended surfaces into a mesh pattern proximate the base die.

In Example 55, the subject matter of any one or more of Examples 53-54 optionally include wherein forming the extended surfaces includes forming a Faraday cage proximate the base die.

Example 56 is a method of manufacturing a stacked package, the method comprising: attaching a base die to a substrate to form a base package, the base package including a central processing unit (CPU); attaching an electrically isolated metal layer to the CPU; and attaching an ancillary package to the base package such that the electrically isolated metal layer is located in between the base package and ancillary package, the ancillary package including a memory die.

In Example 57, the subject matter of Example 56 optionally includes forming a mold layer on top of the electrically isolated metal layer such that the mold layer is located in between the ancillary package and the electrically isolated metal layer.

In Example 58, the subject matter of any one or more of Examples 56-57 optionally include wherein attaching the electrically isolated metal layer to the base die includes attaching the electrically isolated metal layer to a top surface and at least one side surface of the CPU.

In Example 59, the subject matter of any one or more of Examples 56-58 optionally include wherein attaching the electrically isolated metal layer to the CPU includes attaching the electrically isolated metal layer to all but one surface of the CPU.

In Example 60, the subject matter of any one or more of Examples 56-59 optionally include electrically coupling the electrically isolated metal layer to a ground (Vss) reference voltage.

In Example 61, the subject matter of any one or more of Examples 56-60 optionally include forming a through mold interconnect passing through a layer of the base package; and electrically coupling the ancillary package to the electrically isolated metal layer and a trace of the base package.

In Example 62, the subject matter of any one or more of Examples 56-61 optionally include forming a through mold interconnect passing through a layer of the base package; and electrically coupling the ancillary package to a trace of the base package but not the electrically isolated metal layer.

In Example 63, the subject matter of any one or more of Examples 56-62 optionally include forming a plurality of extended surfaces extending from the electrically isolated metal layer.

In Example 64, the subject matter of Example 63 optionally includes wherein forming the extended surfaces includes forming the extended surfaces into a mesh pattern proximate the CPU.

In Example 65, the subject matter of any one or more of Examples 56-64 optionally include wherein forming the extended surfaces includes forming a Faraday cage proximate the CPU.

Example 66 is a method of manufacturing a stacked package, the method comprising: attaching a base die to a substrate to form a base package, the base package including a central processing unit (CPU); attaching an electrically isolated metal layer to the CPU; and attaching an ancillary package to the base package such that the electrically isolated metal layer is located in between the base package and ancillary package, the ancillary package including a transceiver integrated circuit.

In Example 67, the subject matter of Example 66 optionally includes forming a mold layer on top of the electrically isolated metal layer such that the mold layer is located in between the ancillary package and the electrically isolated metal layer.

In Example 68, the subject matter of any one or more of Examples 66-67 optionally include wherein attaching the electrically isolated metal layer to the CPU includes attaching the electrically isolated metal layer to a top surface and at least one side surface of the CPU.

In Example 69, the subject matter of any one or more of Examples 66-68 optionally include wherein attaching the electrically isolated metal layer to the CPU includes attaching the electrically isolated metal layer to all but one surface of the CPU.

In Example 70, the subject matter of any one or more of Examples 66-69 optionally include electrically coupling the electrically isolated metal layer to a ground (Vss) reference voltage.

In Example 71, the subject matter of any one or more of Examples 66-70 optionally include forming a through mold interconnect passing through a layer of the base package; and electrically coupling the ancillary package to the electrically isolated metal layer and a trace of the base package.

In Example 72, the subject matter of any one or more of Examples 66-71 optionally include forming a through mold interconnect passing through a layer of the base package; and electrically coupling the ancillary package to a trace of the base package but not the electrically isolated metal layer.

In Example 73, the subject matter of any one or more of Examples 66-72 optionally include forming a plurality of extended surfaces extending from the electrically isolated metal layer.

In Example 74, the subject matter of Example 73 optionally includes wherein forming the extended surfaces includes forming the extended surfaces into a mesh pattern proximate the CPU.

In Example 75, the subject matter of any one or more of Examples 66-74 optionally include wherein forming the extended surfaces includes forming a Faraday cage proximate the CPU.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplate are examples using any combination or permutation of those elements shown or described (or one or more aspects thereof), either with respect to a particular example (or one or more aspects thereof), or with respect to other examples (or one or more aspects thereof) shown or described herein.

Publications, patents, and patent documents referred to in this document are incorporated by reference herein in their entirety, as though individually incorporated by reference. In the event of inconsistent usages between this document and those documents so incorporated by reference, the usage in the incorporated reference(s) are supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to suggest a numerical order for their objects.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. However, the claims may not set forth features disclosed herein because embodiments may include a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined with reference to the appended claims, along with the full scope of equivalents to which such claims are entitled.

1. A microelectronics package comprising:
a base package including a base die;
an ancillary package including an ancillary component, the ancillary package located on top of the base package; and
an electrically isolated metal layer located at least partially within a layer of the base package such that a portion of the electrically isolated metal layer contacts at least one surface of the base die and is located in between the base die and the ancillary component.

2. The microelectronics package of claim 1, wherein the ancillary component includes a memory die.

3. The microelectronics package of claim 1, wherein the ancillary component includes a transceiver integrated circuit.

4. The microelectronics package of claim 1, wherein the base die includes a central processing unit (CPU) with a platform controller hub (PCH).

5. The microelectronics package of claim 1, wherein the electrically isolated metal layer extends across a footprint of the base package.

6. The microelectronics package of claim 1, wherein the electrically isolated metal layer contacts a top surface and at least one side surface of the base die.

7. The microelectronics package of claim 1, wherein the electrically isolated metal layer contacts all but one surface of the base die.

8. The microelectronics package of claim 1, wherein the electrically isolated metal layer is composed of copper or silver.

9. The microelectronics package of claim 1, wherein a thickness of the electrically isolated metal layer is about 5 microns to about 80 microns.

10. The microelectronics package of claim 1, wherein the electrically isolated metal layer is electrically coupled to a ground reference voltage.

11. The microelectronics package of claim 1, further comprising a through mold interconnect passing through the layer of the base package and electrically coupling the ancillary package to the electrically isolated metal layer and a trace of the base package.

12. The microelectronics package of claim 1, further comprising a through mold interconnect passing through the layer of the base package and electrically coupling the ancillary package to a trace of the base package but not the electrically isolated metal layer.

13. The microelectronics package of claim 1, further comprising a plurality of extended surfaces extending from the electrically isolated metal layer.

14. The microelectronics package of claim 13, wherein the extended surfaces form a mesh pattern proximate the base die.

15. A microelectronics package comprising:
a base package including a central processing unit (CPU);
an ancillary package including a memory die, the ancillary package located on top of the base package; and
an electrically isolated metal layer located at least partially within a layer of the base package such that a portion of the electrically isolated metal layer contacts at least one surface of the CPU and is located in between the CPU and the memory die.

16. The microelectronics package of claim 15, wherein the electrically isolated metal layer contacts a top surface and at least one side surface of the CPU.

17. The microelectronics package of claim 15, wherein the electrically isolated metal layer is electrically coupled to a ground reference voltage.

18. The microelectronics package of claim 15, further comprising a through mold interconnect passing through the layer of the base package and electrically coupling the memory die to the electrically isolated metal layer and a trace of the base package.

19. The microelectronics package of claim 15, further comprising a through mold interconnect passing through the layer of the base package and electrically coupling the memory die to a trace of the base package but not the electrically isolated metal layer.

20. The microelectronics package of claim 15, further comprising a plurality of extended surfaces extending from the electrically isolated metal layer.

21. A microelectronics package comprising:
a base package including a central processing unit (CPU);
an ancillary package including a transceiver integrated circuit, the ancillary package located on top of the base package; and
an electrically isolated metal layer located at least partially within a layer of the base package such that a portion of the electrically isolated metal layer contacts at least one surface of the CPU and is located in between the CPU and the transceiver integrated circuit.

22. The microelectronics package of claim 21, wherein the electrically isolated metal layer contacts all but one surface of the CPU.

23. The microelectronics package of claim 21, further comprising a through mold interconnect passing through the layer of the base package and electrically coupling the transceiver integrated circuit to the electrically isolated metal layer and a trace of the base package.

24. The microelectronics package of claim 21, further comprising a through mold interconnect passing through the layer of the base package and electrically coupling the transceiver integrated circuit to a trace of the base package but not the electrically isolated metal layer.

25. The microelectronics package of claim 21, further comprising a plurality of extended surfaces extending from the electrically isolated metal layer.
